(19) United States
(12) Patent Application Publication
(10) Pub. No.: US 2005/0272382 A1
(43) Pub. Date: Dec. 8, 2005

(54) Wireless communication apparatus

(75) Inventor: Yoshihisa Amano, Nara-shi (JP)

Correspondence Address: BIRCH STEWART KOLASCH & BIRCH, PO BOX 747, FALLS CHURCH, VA, 22040-0747, US

(73) Assignee: Sharp Kabushiki Kaisha

(21) Appl. No.: 11/142,452

(22) Filed: Jun. 2, 2005

(30) Foreign Application Priority Data
Jun. 3, 2004 (JP) 2004-165729

(51) Int. Cl. H04B 1/02; H03C 7/02; H04B 7/02

(52) U.S. Cl. 455/101; 455/103

(57) ABSTRACT

In a wireless communication apparatus which is provided with three transmission systems each including therein a transmission power amplifier for amplifying a signal received and a transmitting antenna for transmitting the amplified signal and which is applicable to an MIMO transmission method for simultaneously transmitting three units of data having mutually different contents, in transmitting single unit of data without use of the MIMO transmission method, power of a transmission signal is dispersed for the transmission by simultaneously transmitting same signals from the transmitting antennas corresponding to the transmission power amplifiers by use of the three transmission power amplifiers included in the three transmission systems.

This application is based on Japanese Patent Application No. 2004-165729 filed on Jun. 3, 2004, the contents of which are hereby incorporated by reference.

### BACKGROUND OF THE INVENTION

1. Field of the Invention

The present invention relates to a wireless communication apparatus that transmits data from a transmitter to a receiver by wireless, and particularly to a wireless communication apparatus employing a Multiple Input Multiple Output (MIMO) transmission method.

2. Description of Related Art

In recent years, more and more wireless communication apparatuses are provided with a plurality of systems each including an antenna, and a transmitting and a receiving circuits. Examples of such wireless communication apparatuses include wireless communication apparatuses employing so-called a diversity reception method that includes two or more reception systems while including only one transmission system. Of these wireless communication apparatuses, particular attention has been focused on wireless communication apparatuses which employ the MIMO transmission method and which are expected for practical use in next-generation wireless Local Area Networks (LANs) or fourth-generation cellular phones.

The MIMO transmission method will be briefly described below. The MIMO transmission method is a known high-speed wireless communication technology that is disclosed in many documents. In the MIMO transmission method, from a plurality of (m, where m is an integer of two or more) transmitting antennas, signals of m kinds of data having mutually different contents are simultaneously transmitted (transmitted in parallel) on the same frequency, and then simultaneously received by a plurality of (n; where n is an integer of two or more) receiving antennas, and then the n types of the received signals that appear interfered are subjected to necessary calculating processing so as to restore the m types of data not interfered. The use of this transmission method permits m-fold increase in only the transmission rate without increasing the occupied frequency bandwidth.

FIG. 7 is a block diagram showing the configuration of a wireless communication apparatus used in the MIMO transmission method where both m and n are equal to 3. The wireless communication apparatus in FIG. 7 includes a transmitter 100 and a receiver 200.

The transmitter 100 includes three transmission systems: the first transmission system 110 (hereinafter sometimes simply referred to as “transmission system 110”); the second transmission system 120 (hereinafter sometimes simply referred to as “transmission system 120”); and the third transmission system 130 (hereinafter sometimes simply referred to as “transmission system 130”). Each of the transmission systems 110, 120, and 130 roughly includes: a transmitting circuit 101 which includes a modulator for modulating an original signal of data to be transmitted, and so on and which outputs the modulated signal to a transmission power amplifier 102 to be described later; the transmission power amplifier 102 which amplifies the fed signal; and a transmitting antenna 103 for transmitting the signal amplified by the transmission power amplifier 102 to the receiver 200. The transmission systems 110, 120, and 130 have the same internal configuration.

The receiver 200 includes three reception systems: the first reception system 210 (hereinafter sometimes simply referred to as “reception system 210”); the second reception system 220 (hereinafter sometimes simply referred to as “reception system 220”); and the third reception system 230 (hereinafter sometimes simply referred to as “reception system 230”). Each of the reception systems 210, 220, and 230 roughly includes: a receiving antenna 4 for receiving a signal transmitted from any of the transmission systems included in the transmitter 100; and a receiving circuit 5 that includes a demodulator for demodulating the signal received by any of the receiving antennas 4, and so on. The reception systems 210, 220, and 230 have the same internal configuration.

Broken lines 300 with arrows shown in FIG. 7 schematically show how radio wave propagation including interference occurs between the three transmission systems and the three reception systems.

FIG. 8 schematically shows the spectra of signals transmitted by the three transmission systems 110, 120, and 130. This figure shows, from the top, the spectrum 301 of the signal transmitted by the first transmission system 110; the spectrum 302 of the signal transmitted by the second transmission system 120; and the spectrum 303 of the signal transmitted by the third transmission system 130. The signals corresponding to the spectra 301, 302, and 303, respectively, are mutually different signals although they have common frequency components. That is, the three transmission systems transmit their respective different signals (the signals corresponding to the spectra 301, 302, and 303) on the same frequency in a multiplexed manner. The signals corresponding to the spectra 301, 302, and 303 respectively, are signals that are modulated by an Orthogonal Frequency Division Multiplexing (OFDM) modulation method (OFDM-modulated signals) and are in 5 GHz band.

The OFDM modulation method is one type of multicarrier transmission methods that divide data to be transmitted into a plurality of carrier waves. It is assumed that each of the signals corresponding to the spectra 301, 302, and 303, respectively, is a multicarrier signal including nine subcarriers. Specifically, each of the signals corresponding to the spectra 301, 302, and 303, respectively, is transmitted as a multicarrier signal obtained by dividing data to be transmitted into nine subcarriers.

As shown in FIGS. 7 and 8, an operation employing the original MIMO transmission method, in which a plurality of (three in FIG. 7) transmission systems simultaneously transmit their respective different signals on the same frequency and then the transmitted signals are received simultaneously by a plurality of (three in FIG. 7) receiving antennas 4, is hereinafter referred to as an “MIMO operation”. The time during which such an operation is performed is referred to as “in the MIMO operation”.

Most of wireless communication apparatuses designed for use in the MIMO transmission method generally are so designed as to be operable in conventional transmission methods (non-MIMO transmission methods) different from the MIMO transmission method for the purpose of ensuring compatibility with conventional apparatuses that are not used (or cannot be used) in the MIMO transmission method. Such an operation in the non-MIMO transmission method is generally achieved by maintaining one of the transmission systems and one of the reception systems shown in FIG. 7 while halting the remaining transmission and reception systems. Specifically, the operation in the non-MIMO transmission method is achieved by, for example, performing conventional one-to-one communication between the first transmission system 110 and the first receiving system 210 while halting the transmission systems 120 and 130 and the reception systems 220 and 230.

FIG. 9 schematically shows the spectra of signals transmitted by the three transmission systems (110, 120, and 130) in the one-to-one communication. This figure shows, from the top, the spectrum 401 of the signal transmitted by the first transmission system 110; the spectrum of the signal transmitted by the second transmission system 120; and the spectrum of the signal transmitted by the third transmission system 130. As shown in this figure, only the first transmission system 110 transmits a signal, and the second and third transmission systems 120 and 130 transmit no signals.

In contrast to the “MIMO operation” described above, an operation not employing the MIMO transmission method is referred to as a “non-MIMO operation”, and the time during which the non-MIMO operation is performed is referred to as “in the non-MIMO operation”.

The configuration for transmitting an OFDM-modulated signal by the MIMO transmission method as described above is disclosed in, for example, the article “Optimal Power Allocation Based on Minimum BER Criterion In MIMO-OFDM System” (included in the IEICE (Institute of Electronics, Information, and Communication Engineers, Japan) 2003 Society Conference Lecture Collection, article no.: B-5-30, published by IEICE, Sep. 10, 2003) (hereinafter referred to as “document 1”). The document 1 described above discloses the configuration that adjusts the power of spectra of a plurality of signals transmitted to be uneven for the purpose of eliminating unevenness in the reception power among sub-channels in the fading condition.

Multicarrier transmission systems other than the OFDM modulation method includes, for example, Variable Spreading Factor-Code Division Multiple Access (VSF-CDMA) method that is under study for use in the fourth-generation cellular phones. The VSF-CDMA method is disclosed in, for example, the article “Adaptive Transmission Timing Control Using Reservation Packet in Reverse Link for VSF-CDMA Broadband Wireless Access” (included in the IEICE (Institute of Electronics, Information, and Communication Engineers, Japan) 2003 Society Conference Lecture Collection, article no.: B-5-94, published by IEICE, Sep. 10, 2003).

Configuring a conventional wireless communication apparatus employing the MIMO transmission method so as to support even the non-MIMO operation as described above causes a problem of degrading the efficiency of the transmission power amplifier. This problem is attributable to the upper limit of transmission power from the transmitter being restricted by the regulations, such as Radio Law, of respective countries. The cause of the problem will be described below with reference to FIGS. 7, 8, and 9. In this specifications, description will be given hereinafter based on the assumption that the upper limit of transmission power is 100 milliwatt (mW).

In the MIMO operation, the signals corresponding to the spectra 301, 302, and 303, respectively (see FIG. 8), are transmitted simultaneously. If the transmission power is evenly allocated, the three signals corresponding to the spectra 301 to 303, respectively, each have a maximum power of approximately 33 mW (because of 100 mW÷3≈33 mW). Contrarily, in the non-MIMO operation, the signal corresponding to the spectrum 401 (see FIG. 9) transmitted by the first transmission system 110 has a maximum power of 100 mW (because the second and third transmission systems 120 and 130 shown in FIG. 7 are in a halt state).

Specifically, focusing on only the transmission power amplifier 102 included in the first transmission system 110, there is a threefold difference (33 mW versus 100 mW) in the treated operating power level between in the MIMO and non-MIMO operations. Such fluctuation in the operating power level generally causes degradation of the efficiency of a power amplifier (e.g. the transmission power amplifier 102), which is to be discussed with reference to FIG. 10.

FIG. 10 shows the relationship between the output power and the efficiency in the transmission power amplifier 102. In FIG. 10, the horizontal axis indicates the output power, and curves 501 and 502 indicate the gain characteristic (in the unit of “dB”) and the power added efficiency (PAE; in the unit of “%”) characteristic, respectively, of the transmission power amplifier 102.

As shown in FIG. 10, the power added efficiency increases with increasing output power and reaches its maximum value around a saturation output power Psat1 (the maximum power that can be outputted by the transmission power amplifier 102). Around the saturation output power Psat1 (the region surrounded by a broken line 503 in FIG. 10), however, the linearity of gain characteristic deteriorates, and the outputted signal waveform is largely distorted. Therefore, the transmission power amplifier 102 is generally operated at output power a little smaller than the saturation output power Psat1. The difference between the saturation output power Psat1 and the output power actually used for operation (operating output power) is called backoff.

Now, it is assumed that the backoff of the transmission power amplifier 102 included in the first transmission system 110 in the non-MIMO operation is B1, and the operating output power thereof and the power added efficiency thereof in this condition are P1 and E1, respectively. It is also assumed that the backoff of each of the transmission power amplifiers 102 included in the transmission systems 110, 120, and 130, respectively, in the MIMO operation is B2, and the operating output power thereof and the power added efficiency thereof in this condition are P2 and E2, respectively.

When the operating power level of the transmission power amplifier 102 included in the first transmission system 110 in the non-MIMO operation is 100 mW, the operating output power P1 obtained by subtracting the backoff B1 from the saturation output power Psat1 is designed at 100 mW. For example, when the OFDM modulation system is adopted according to the standard IEEE 802.11, this backoff B1 needs to be set relatively large, and thus the power added efficiency inevitably needs to be set relatively small(, which is attributable to a relatively large ratio of the average power to the instantaneous maximum power and to a relatively small permitted distortion).

Now, discussion will be made, referring to a case where transfer occurs from the non-MIMO operation to the MIMO operation. At this point of time, the operating output power of the transmission power amplifier 102 included in the first transmitting system 110 becomes P2. If the transmission power is evenly allocated as described above, the operating output power of each of the transmission power amplifiers 102 decreases down to 33 mW. Specifically, each of the transmission power amplifiers 102 operates at the operating output power P2, where the backoff B2 is employed which is even larger than the backoff in the non-MIMO operation. Thus, the power added efficiency decreases down to a considerably small value (E2).

Due to the reason described above, the conventional wireless communication apparatus employing the MIMO transmission method has had the problem of considerably degrading the efficiency of the power transmission amplifier when configured to support even the non-MIMO operation.

The example of the conventional configuration recited in the document 1 is intended to adjust the power of spectra of a plurality of signals transmitted to be uneven for the purpose of eliminating unevenness in the reception power among sub-channels in the fading condition, and thus is not intended to solve the problem of degrading the efficiency of the transmission power amplifier as described above.

### SUMMARY OF THE INVENTION

In view of the problem described above, it is an object of the present invention to provide a wireless communication apparatus that can achieve improvement in the power added efficiency of a transmission power amplifier.

To achieve the object described above, according to one aspect of the present invention, a wireless communication apparatus is provided with M transmission systems, where M is an integer of two or more, each including therein a transmission amplifier for amplifying a signal received and a transmitting antenna for transmitting the amplified signal. The wireless communication apparatus is applicable to a transmission method for simultaneously transmitting a plurality of units of data having mutually different contents. In the wireless communication apparatus, in transmitting a single unit of data without use of the transmission method, power of a transmission signal is dispersed for the transmission by use of a plurality of the transmission amplifiers included in the M transmission systems.

The upper limit of the transmission power exerted by an entire wireless communication apparatus is generally specified by the standard or the like. In the conventional example, using a transmission amplifier so as to provide the transmission power at the upper limit in both cases where the transmission method is used and where it is not used has resulted in degradation in the power added efficiency of the transmission amplifier. This degradation is attributable to one transmission amplifier outputting the transmission power at the upper limit, which has caused fluctuation in the operating output power of the transmission amplifier between when the transmission method is used and when it is not used.

According to the configuration described above, however, in transmitting the data by the transmission method, the plurality of the transmission amplifiers are used so that a plurality of units of data are transmitted in parallel. Moreover, in transmitting the single unit of data without use of the transmission method, the plurality of the transmission amplifiers are used so that the power of the transmission signal is dispersed.

That is, whether or not the transmission method is used, the plurality of the transmission amplifiers operate so that the transmission signals are radiated from the transmitting antennas corresponding to the plurality of the transmission amplifiers, respectively.

Therefore, in each of the transmission amplifiers, the fluctuation in the operating output power between when the transmission method is used and when it is not used is controlled smaller than that in the conventional example, thereby achieving the improvement in the efficiency of each of the transmission amplifiers.

Specifically, in transmitting the single unit of data without use of the transmission method, the power of the transmission signal may be dispersed for the transmission by simultaneously transmitting signals of a same signal waveform from a plurality of the transmitting antennas corresponding to the plurality of the transmission amplifiers by use of the plurality of the transmission amplifiers.

The “same signal waveform” described above is a concept not including the signal's strength, and thus becomes synonymous with “same signal” if the signal's strength is the same.

For example, the plurality of the transmission amplifiers may correspond to all the transmission amplifiers included in the M transmission systems.

For example, in transmitting the single unit of data without use of the transmission method, the power of the transmission signal may be dispersed for the transmission through even power allocation by use of the plurality of the transmission amplifiers.

This achieves more optimized improvement in the efficiency of each of the transmission amplifiers. The term “even” does not mean “completely even”, but is a concept including small variation such as is caused by allocation error.

For example, a modulated signal corresponding to the single unit of data may be a multicarrier signal including N subcarriers, where N is an integer of two or more. In transmitting the single unit of data without use of the transmission method, the N subcarriers may be dispersed for allocation to a plurality of the transmission systems in the M transmission systems, so that the plurality of the transmission systems independently amplify the respective mutually different subcarriers thereof and then independently transmit the subcarriers.

When a signal to be amplified by the transmission amplifier is a multicarrier signal, the instantaneous fluctuation in the operating output power of the transmission power amplifier is relatively large, which requires ensuring relatively large backoff. The larger the number of subcarriers included in the multicarrier signal is, the larger the backoff to be ensured needs to be controlled. In the configuration described above, however, when the transmission method is not used, the subcarriers are dispersed for the allocation to the plurality of the transmission systems so that the number of subcarriers to be amplified by the transmission amplifier in each of the transmission systems decreases, thereby achieving a decrease in the backoff.

At this point of time, the backoff decreases and the efficiency of each of the transmission amplifiers further improves by, while maintaining the operating output power of the transmission amplifiers at the same value, controlling the saturation output power of the transmission amplifier included in each of the plurality of transmission systems smaller than the saturation output power adopted when the transmission method is used.

For example, the plurality of the transmission systems may correspond to all the transmission systems in the M transmission systems.

For example, in transmitting the single unit of data without use of the transmission method, the N subcarriers may be dispersed for the allocation so as to minimize variation in the number of the subcarriers allocated among the plurality of the transmission systems.

This achieves more optimized improvement in the efficiency of each of the transmission amplifiers.

As a detailed example, the transmission method is a MIMO transmission method.

### BRIEF DESCRIPTION OF THE DRAWINGS

FIG. 1 is a block diagram of a wireless communication apparatus according to a first embodiment of the present invention;

FIG. 2 is a block diagram of the wireless communication apparatus of FIG. 1 in non-MIMO operation;

FIG. 3 is a diagram showing the relationship between the output power and the efficiency in each of the transmission power amplifiers of FIG. 1;

FIG. 4 is a diagram schematically showing the spectra of signals transmitted by the respective transmission systems of FIG. 1 in the non-MIMO operation;

FIG. 5 is a diagram showing the relationship between the output power and the efficiency in each of transmission power amplifiers according to a second embodiment of the present invention;

FIG. 6 is a diagram schematically showing the spectrum of a signal transmitted from a transmitter according to a third embodiment of the present invention;

FIG. 7 is a block diagram of a conventional wireless communication apparatus;

FIG. 8 is a diagram schematically showing the spectra of signals transmitted from a transmitter in MIMO operation;

FIG. 9 is a diagram schematically showing the spectra of signals transmitted from the transmitter of FIG. 7 in the non-MIMO operation; and

FIG. 10 is a diagram showing the relationship between the output power and the efficiency in each of the transmission power amplifiers of FIG. 7.

### DETAILED DESCRIPTION OF PREFERRED EMBODIMENTS

### First Embodiment

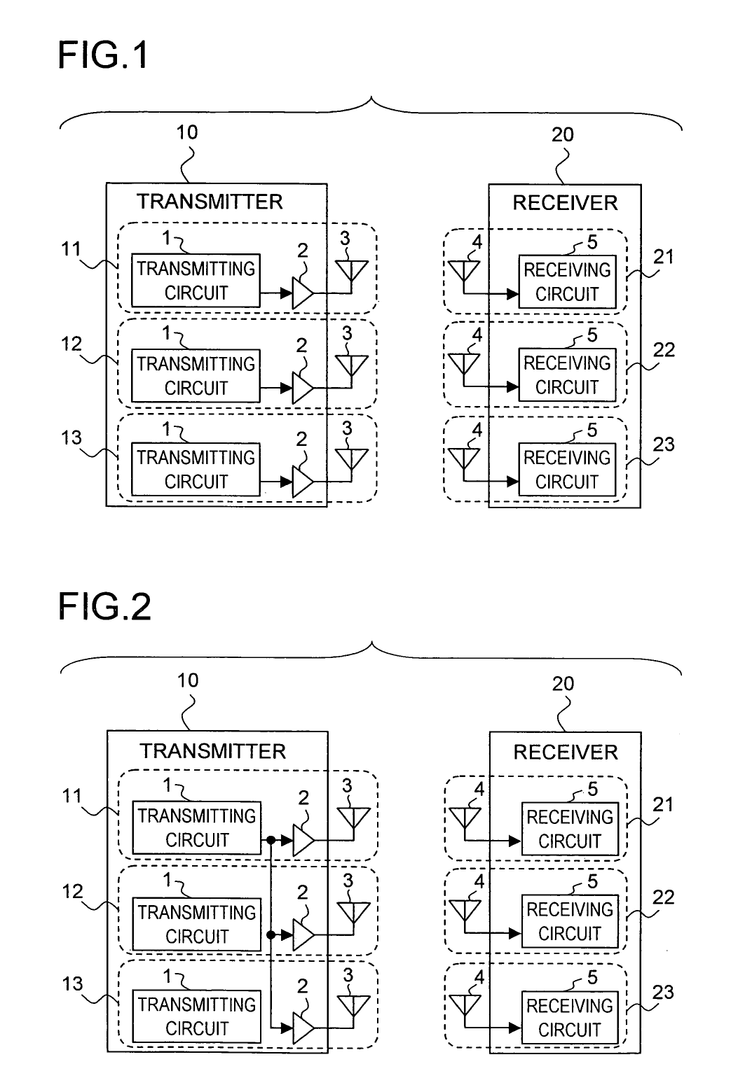

A first embodiment of a wireless communication apparatus according to the present invention will be described below with reference to the accompanying drawings. FIG. 1 is a block diagram showing the configuration of the wireless communication apparatus according to the first embodiment. In FIG. 1, portions corresponding to those shown in FIG. 7 are provided with the same numerals, and thus description of some of the details thereof may be omitted. The wireless communication apparatus in FIG. 1 includes a transmitter 10 and a receiver 20.

The transmitter 10 includes three transmission systems: the first transmission system 11 (hereinafter sometimes simply referred to as “transmission system 11”); the second transmission system 12 (hereinafter sometimes simply referred to as “transmission system 12”); and the third transmission system 13 (hereinafter sometimes simply referred to as “transmission system 13”). Each of the transmission systems 11, 12, and 13 roughly includes: a transmitting circuit 1 which includes a modulator for modulating an original signal of data to be transmitted, and so on and which outputs the modulated signal to a transmission power amplifier 2 to be described later; the transmission power amplifier (transmission amplifier) 2 which amplifies the fed signal; and a transmitting antenna 3 for transmitting the signal amplified by the transmission power amplifier 2 to the receiver 20. The transmission systems 11, 12, and 13 have the same internal configuration, except for the point to be specified later.

The receiver 20 includes three reception systems: the first reception system 21 (hereinafter sometimes simply referred to as “reception system 21”); the second reception system 22 (hereinafter sometimes simply referred to as “reception system 22”); and the third reception system 23 (hereinafter sometimes simply referred to as “reception system 23”). Each of the reception systems 21, 22, and 23 roughly includes: a receiving antenna 4 for receiving a signal transmitted from any of the transmission systems included in the transmitter 10; and a receiving circuit 5 that includes a demodulator for demodulating the signal received by any of the receiving antennas 4, and so on. The reception systems 21, 22, and 23 have the same internal configuration.

The wireless communication apparatus shown in FIG. 1 is, like a wireless communication apparatus shown in FIG. 7, capable of transmitting data by the MIMO transmission method. In the MIMO operation, from the respective transmitting antennas 3 included in the transmission systems 11, 12, and 13, signals of data having mutually different contents are simultaneously transmitted (transmitted in parallel) on the same frequency, and then the transmitted signals are simultaneously received by each of the receiving antennas 4 included in the reception systems 21, 22, and 23. That is, the transmitting antenna 3 in the first transmission system 11, the transmitting antenna 3 in the second transmission system 12, and the transmitting antenna 3 in the third transmission system 13 simultaneously transmit the signal of the first data, the signal of the second data, and the signal of the third data (the first, second, and third data have mutually different contents), respectively, on the same frequency. Then, each of the receiving antennas 4 included in the reception systems 21, 22, and 23 simultaneously receives the signal of the first data, the signal of the second data, and the signal of the third data.

Then the three types of the received signals that appear interfered are subjected to necessary calculating processing in a restoring portion, not shown, included in the receiver, so that the three types of data (first data, second data, and third data) not interfered are restored.

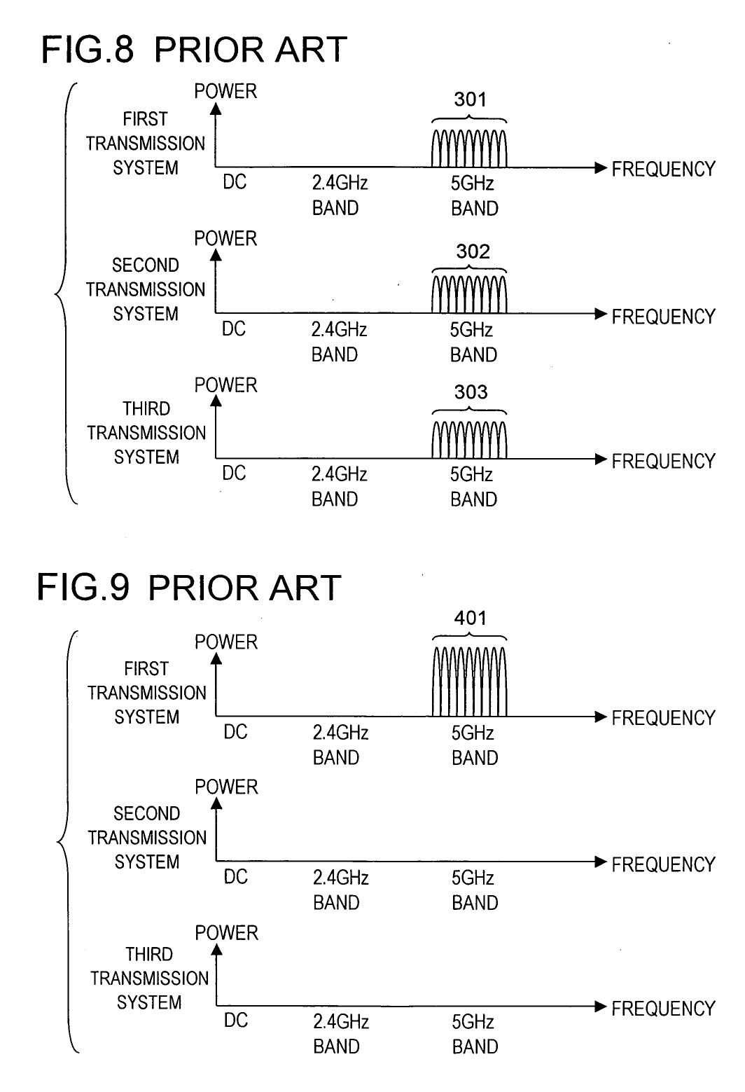

When the wireless communication apparatus shown in FIG. 1 adopts the OFDM modulation method, the spectrum of the signal transmitted by the first transmission system 11, the spectrum of the signal transmitted by the second transmission system 12, and the spectrum of the signal transmitted by the third transmission system 13 in the MIMO operation are the same as the spectrum 301, the spectrum 302, and the spectrum 303, respectively, shown in FIG. 8. Thus, the three transmission systems (11, 12, and 13) simultaneously transmit the mutually different signals (signals corresponding to the spectrum 301, the spectrum 302, and the spectrum 303, respectively) on the same frequency. In both the MIMO operation and non-MIMO operations, the OFDM modulation method or another type of method may be used to transmit signals. The description given below is based on the assumption that the OFDM modulation method is used.

Description of the Non-MIMO Operation

Next, description will be given concerning the non-MIMO operation performed by the wireless communication apparatus shown in FIG. 1. In the non-MIMO operation, the MIMO transmission method is not adopted in which a plurality of units of data are simultaneously transmitted in parallel on the same frequency. Instead, in the non-MIMO operation, only a single unit of data is transmitted from the transmitter 10 to the receiver 20. Therefore, in transmitting two units of data including the first and second data, the first and second data are not transmitted in parallel but in a time-division manner.

FIG. 2 is a block diagram showing the configuration of the wireless communication apparatus of this embodiment in the non-MIMO operation. It is now assumed that “data A” as a single unit of data is transmitted by the non-MIMO operation. In the non-MIMO operation, each of transmitting circuits 1 in the transmission systems 12 and 13 is halted to save power consumption, whereas each of the transmission power amplifiers 2 in the transmission systems 12 and 13 operates without being halted.

An output signal of the transmitting circuit 1 in the first transmission system 11 is fed to each of the transmission power amplifiers 2 in the transmission systems 11, 12, and 13. To achieve this, the output signal of the transmitting circuit 1 in the first transmission system 11 is distributed to each of the transmission power amplifiers 2 included in the transmission systems 11, 12, and 13, respectively (hereinafter, each of the transmission power amplifiers 2 in the transmission systems 11, 12, and 13 may be sometimes simply referred to as “each of the transmission power amplifiers 2”) so that the power radiated from the respective transmitting antennas 3 in the transmission systems 11, 12, and 13 is equalized and the sum of the power radiated from the transmitting antennas 3 does not exceed the upper limit, i.e., 100 mW. As a result, the same transmission signals of the “data A” are simultaneously radiated from the respective transmitting antennas 3 in the transmission systems 11, 12, and 13.

Specifically, in transmitting the “data A” as a single unit of data by the non-MIMO operation (without use of the MIMO transmission method), by using the three transmission power amplifiers 2, the same signals are simultaneously transmitted from the transmitting antennas 3 connected to the three transmission power amplifiers 2, respectively, thereby dividing, through even allocation, the power of the transmission signals from the entire transmitter 10. The term “even” does not mean “completely even”, but is a concept including small variation such as is caused by allocation error.

In the transmitter 20 in the non-MIMO operation, the operations of the second and third reception systems 22 and 23 are halted, and only the first reception system 21 operates. The receiving antenna 4 in the reception system 21 receives the signals transmitted from the respective transmitting antennas 3 in the transmission systems 11, 12, and 13. Then the received signals are subjected to demodulation, etc. in the receiving circuit 5 in the reception system 21.

In the non-MIMO operation, the output signal of the transmitting circuit 1 in the first transmission system 11 may be fed to each of the transmission power amplifiers 2 in the transmission systems 11, 12, and 13 by, for example, providing a switch (not shown) which is configured as follows. The switch connects together the output side of the transmitting circuit 1 included in the first transmission system 11 and the input side of the transmission power amplifier 2 included in the second transmission system 12, and also connects together the output side of the transmitting circuit 1 included in the first transmission system 11 and the input side of the transmission power amplifier 2 included in the third transmission system 13. The switch is set ON in the non-MIMO operation and OFF in the MIMO operation. In FIG. 2, the output side of the transmitting circuit 1 included in the second transmission system 12 is not connected with the input side of the transmission power amplifier 2 included in the second transmission system 12, and also the output side of the transmitting circuit 1 included in the third transmission system 13 is not connected with the input side of the transmission power amplifier 2 included in the third transmission system 13. However, they do not necessarily have to be disconnected, but may be kept connected together as shown in FIG. 1.

As described above, in the non-MIMO operation, only one of the reception systems is required to operate. Thus, instead of the receiver 20, a receiver may be used which is initially provided with only one reception system (e.g., the first reception system 21). It is also absolutely acceptable to use, instead of the receiver 20, a receiver that employs a diversity reception method. In this case, two or more receiving antennas are used to receive signals transmitted from the respective transmitting antennas 3 in the transmission systems 11, 12, and 13.

Reason for the Improved Efficiency

Next, the reason why the efficiency of the transmission power amplifier 2 in the wireless communication apparatus of FIG. 1 configured as described above has improved compared to that of the conventional example. As described above, the description will be given based on the assumption that the upper limit of transmission power of the transmission signals radiated from the entire transmitter 10 is 100 mW.

In the MIMO operation performed by the wireless communication apparatus of this embodiment, the signals corresponding to the spectra 301, 302, and 303, respectively (see FIG. 8), are simultaneously transmitted. Therefore, assuming that the transmission power is evenly allocated, the maximum power of each of the three signals corresponding to the spectra 301, 302, and 303, respectively, is approximately 33 mW (one third of 100 mW). That is, the operating output power of each of the transmission power amplifiers 2 is approximately 33 mW (one third of 100 mW) (this point is similar to what is shown in FIG. 7).

In the non-MIMO operation, the output signal of the transmitting circuit 1 in the first transmission system 11 is distributed to each of the transmission power amplifiers 2 in the transmission systems 11, 12, and 13 in a manner such that the power radiated from the respective transmitting antennas 3 in the transmission systems 11, 12, and 13 is equalized. Therefore, in order to set the maximum transmission power in the non-MIMO operation at 100 mW, each transmission power may be set at approximately 33 mW (one third of 100 mW).

That is, the operating output power of each of the transmission power amplifiers 2 can constantly be set at approximately 33 mW in both the MIMO and non-MIMO operations.

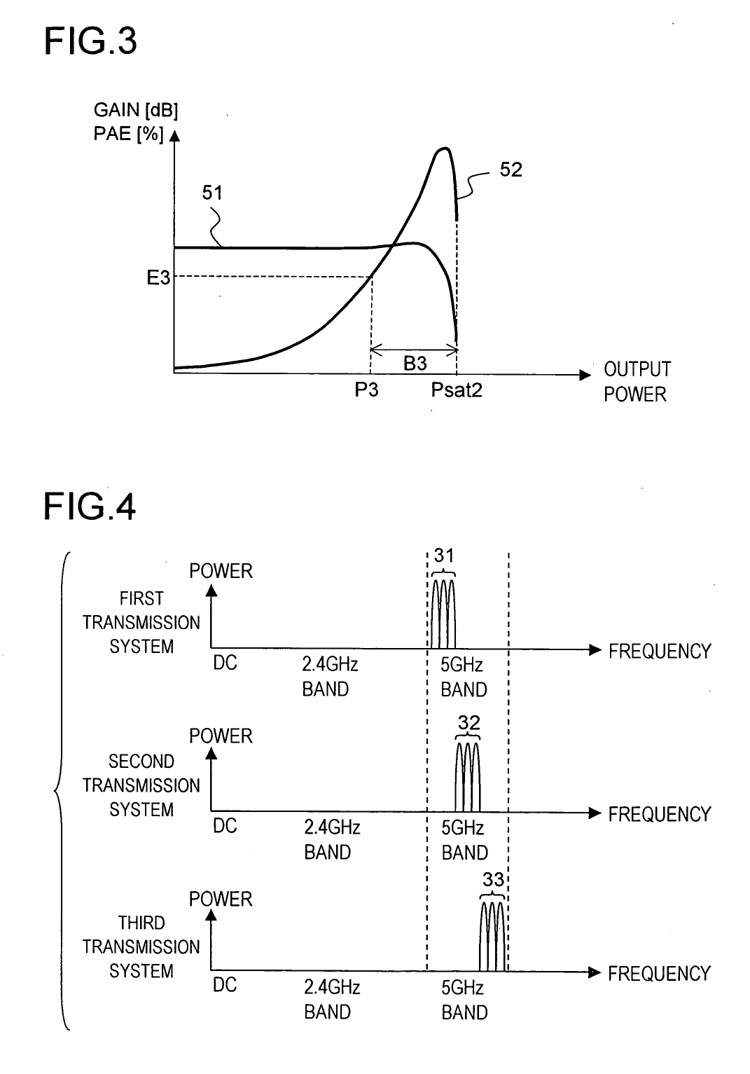

FIG. 3 shows the relationship between the output power and the efficiency in each of the transmission power amplifiers 2 of this embodiment. In FIG. 3, the horizontal axis indicates the output power, and curves 51 and 52 indicate the gain characteristic (in the unit of “dB”) and the power added efficiency (PAE; in the unit of “%”) characteristic, respectively, of each of the transmission power amplifiers 2.

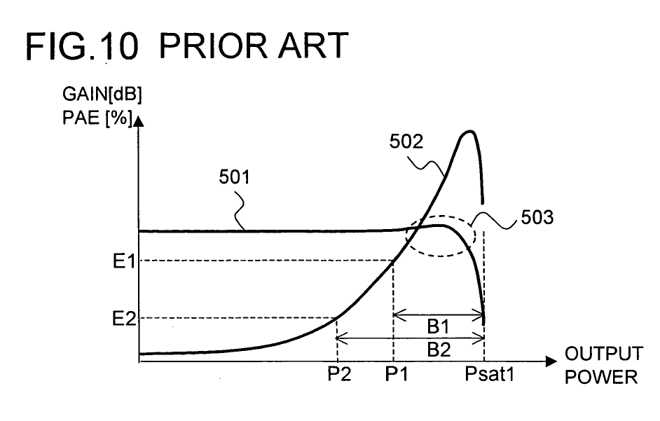

As shown in FIG. 3, the power added efficiency increases with increasing output power and reaches its maximum value around a saturation output power Psat2 (the maximum power that can be output by the transmission power amplifier 2), as is the case with the power added efficiency of the transmission power amplifier 102 (see FIG. 7) shown by the curve 502 in FIG. 10.

Since each of the transmission power amplifiers 2 in this embodiment has an operating output power of approximately 33 mW (one third of 100 mW) in both the MIMO and non-MIMO operations, the backoff in both the MIMO and non-MIMO operations can mutually be set at B3 (see FIG. 3). When the backoff is set at B3, the operating output power and the power added efficiency are represented as P3 and E3, respectively.

Since the operating output power P3 (approximately 33 mW) is smaller than 100 mW, i.e., the operating output power P1 (FIG. 10) in the non-MIMO operation in the convention example, the transmission power amplifier 2 is configured such that the saturation output power Psat2 of the transmission power amplifier 2 is set smaller than the saturation output power Psat1 (FIG. 10) of the transmission power amplifier 102 (FIG. 7) in the conventional example.

The backoff B3 of the transmission power amplifier 2 can be set equal (or substantially equal) to the backoff B1 in FIG. 10. The following description is based on the assumption that the backoff B1 and the backoff B3 are equal to each other. Thus, the power added efficiency E3 is equal (or substantially equal) to the power added efficiency E1 of the transmission amplifier 102 (FIG. 7) in the non-MIMO operation in the conventional example.

In the MIMO operation, however, there arises significant difference in the power added efficiency between the transmission power amplifier 2 and the transmission power amplifier 102 (FIG. 7) of the conventional example. In the MIMO operation, the power added efficiency of the transmission power amplifier 102 (FIG. 7) of the conventional example considerably decreases from E1 to E2. On the other hand, the power added efficiency of the transmission power amplifier 2 of this embodiment does not change, but stays E3, the same as that in the non-MIMO operation. Therefore, the power added efficiency of the transmission power amplifier 2 of this embodiment significantly improves compared to that in the conventional example.

### Second Embodiment

Next, the second embodiment of a wireless communication apparatus according to the present invention will be described below with reference to the accompanying drawings. The configuration of the wireless communication apparatus according to the second embodiment is the same as that of the wireless communication apparatus of the first embodiment; therefore, it is omitted from the description. Moreover, the MIMO operation in the second embodiment is the same as that in the first embodiment. The wireless communication apparatus of the second embodiment is different from the wireless communication apparatus of the first embodiment in that, when the OFDM modulation method is adopted in the non-MIMO operation, the method of dispersing the power is further optimized.

Thus, the non-MIMO operation, the unique feature of this embodiment, will be described below. The configuration of the wireless communication apparatus of this embodiment in the non-MIMO operation is the same as that shown in FIG. 1, but different from that (FIG. 2) of the first embodiment in the non-MIMO operation. It is now assumed that “data B” as a single unit of data is transmitted by the non-MIMO operation by use of the OFDM modulation method. It is also assumed that, when the “data B” is modulated by the OFDM modulation method, the OFDM modulated signal thereof becomes a multicarrier signal (hereinafter this multicarrier signal is referred to as “multicarrier signal B”) including nine subcarriers. That is, the “data B” to be transmitted is transmitted as the multicarrier signal B including the nine divided subcarriers.

In this embodiment, the nine subcarriers are evenly (i.e., 3 for each) distributed (dispersed for allocation) to three transmission systems 11, 12, and 13. How this distribution is achieved will be described with reference to FIG. 4. FIG. 4 schematically shows the spectra of signals transmitted by the three transmission systems 11, 12, and 13. This figure shows: from the top, a spectrum 31 of the signal transmitted by the first transmission system 11; a spectrum 32 of the signal transmitted by the second transmission system 12; and a spectrum 33 of the signal transmitted by the third transmission system 13. The signals corresponding to the spectra 31, 32, and 33, respectively, each includes three subcarriers, and their carrier wave frequencies are different from one another. Synthesizing the spectra 31, 32, and 33 generates the multicarrier signal B described above. The signals corresponding to the spectra 31, 32, and 33, respectively, are each in a 5 GHz-band, as those shown in FIG. 8.

Thus, in transmitting the single “data B” by the non-MIMO operation (without use of the MIMO transmission method), the subcarriers are dispersed into three each for the allocation to the three transmission systems 11, 12, and 13, respectively, which then independently amplify their mutually different subcarriers. In this transmission, the operating output power of each of transmission power amplifiers 2 is approximately 33 mW (one third of 100 mW).

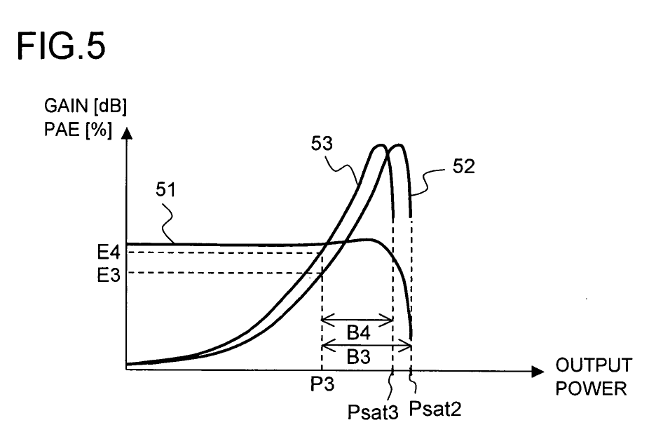

FIG. 5 shows the relationship between the output power and the efficiency in each of the transmission power amplifiers 2 in this embodiment. In FIG. 5, the horizontal axis indicates the output power, and a curve 51 indicates the gain characteristic of the transmission power amplifier 2 (in the unit of “dB”). A curve 52 indicates the power added efficiency characteristic of each of the transmission power amplifiers 2 in the MIMO operation. The curves 51 and 52 are identical to those shown in FIG. 3.

In the MIMO operation, as in the first embodiment, the operating output power P3 of each of the transmission power amplifiers 2 is approximately 33 mW (one third of 100 mW), and the backoff and the power added efficiency thereof are B 3 and E3, respectively. In the non-MIMO operation, as described above, the operating output power P3 of each of the transmission power amplifiers 2 is also approximately 33 mW (one third of 100 mW). Regardless of whether the MIMO operation or the non-MIMO operation, therefore, the operating output power of each of the transmission power amplifiers 2 does not change, thus achieving great improvement in the power added efficiency in the MIMO operation for the same reason as explained in the first embodiment (the first effect of this embodiment).

In the non-MIMO operation, the saturation output power of each of the transmission power amplifiers 2 is decreased from Psat2, the value in the MIMO operation, to Psat3 (Psat2>Psat3). As a method for decreasing the saturation output power of each of the transmission power amplifiers 2, any of the well-known methods disclosed in many documents may be adopted; therefore, description of this method is omitted here.

A curve 53 indicates the power added efficiency characteristic of each of the transmission power amplifiers 2, when the saturation output power is decreased to Psat3. The fact that the operating output power of each of the transmission power amplifiers 2 is maintained at approximately 33 mW although the saturation output power is decreased from Psat2 to Psat 3 means that the backoff of each of the transmission power amplifiers 2 in the non-MIMO operation is decreased from B3 to B4 (B3>B4). However, no problem arises for the following reason since the number of subcarriers to be amplified by each of the transmission power amplifiers 2 is decreased to one third (because 3/9=⅓).

Multicarrier signals modulated by the OFDM modulation method or the like have subcarriers intensifying or attenuating one another in accordance with the phase difference among them that change with time. Therefore, the instantaneous fluctuation in the operating output power of the transmission power amplifier is extremely large (for example, in a case where signals of subcarriers are superimposed in phase, instantaneous signal amplitude becomes extremely larger than the average).

In view of this instantaneous fluctuation, the transmission power amplifier needs to be operated in the linear region (amplification is performed while controlling the signal distortion within the range specified by the standard, etc.), which requires providing relatively large backoff (in this embodiment, the backoff needs to be set B3 so as to amplify nine subcarriers by one transmission power amplifier 2). However, in the non-MIMO operation of this embodiment, the number of subcarriers to be amplified by each of the transmission power amplifiers 2 is decreased to one third. Therefore, the instantaneous fluctuation described above is kept small, so that each of the transmission power amplifier 2 operates in the linear region even when the backoff decreases to B4, thus causing no problem attributable to the decreased backoff.

As is understood from the above description, the smaller the number of subcarriers to be amplified by each of the transmission power amplifiers 2 is, the smaller the instantaneous fluctuation described above is kept, which permits the backoff to decrease.

In the wireless communication apparatus of this embodiment, in the non-MIMO operation, the decrease of backoff from B3 to B4 results in further improvement in the power added efficiency from E3 to E4 (E3<E4) (the second effect of this embodiment). The power added efficiency E3 is equal to the power added efficiency E1 (FIG. 10) achieved by the conventional example in the non-MIMO operation; therefore E1<E4 is satisfied. Thus, it can also be said that the power added efficiency (E4) in the non-MIMO operation can be more greatly improved than that (E1) achieved by the conventional example shown in FIG. 7.

### Third Embodiment

The second embodiment described above is widely applicable to communication systems that handle a multicarrier signal including two or more subcarriers, and not limited to the OFDM modulation method. Hereinafter, a modification of the second embodiment in a case where a VSF-CDMA method is adopted will be described as the third embodiment.

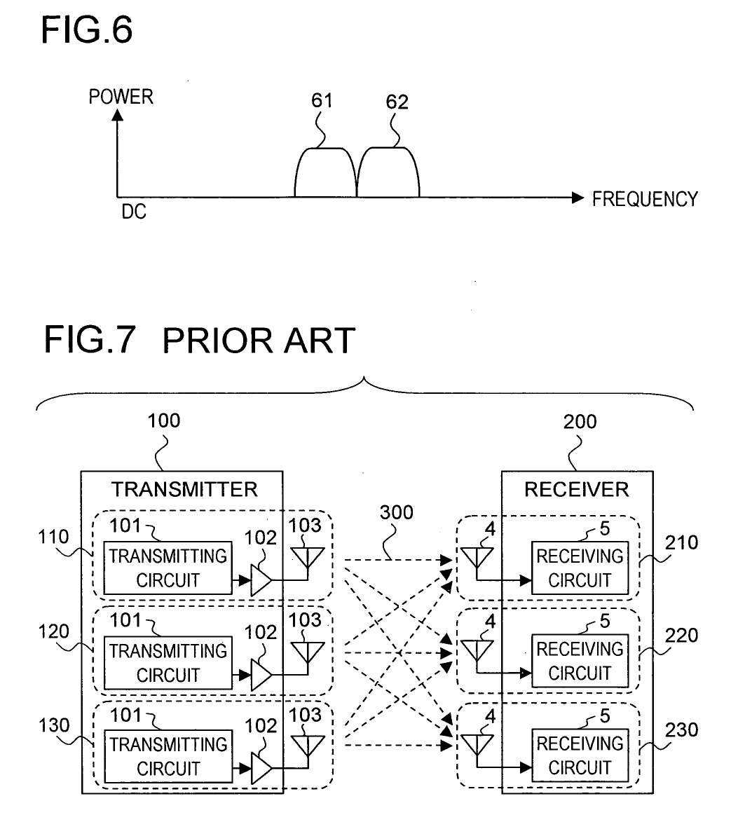

FIG. 6 schematically shows the spectrum of a signal transmitted from the transmitter 10 when the VSF-CDMA method is adopted. This signal is formed by arranging on the frequency axis two carriers' worth of spectra 61 and 62 that correspond to a CDMA signal having a band width of 20 MHz, thus having a total band width of 40 MHz. The VSF-CDMA method is also one type of multicarrier transmission methods that divide data to be transmitted into a plurality of carrier waves for transmission. The data to be transmitted is transmitted as a multicarrier signal having the two divided subcarriers (61, 62).

When the signal as shown in FIG. 6 is handled, the second embodiment can be modified as shown in (1) and (2) below. (Only the modified portions are indicated since the third embodiment is a modification of the second embodiment.) The MIMO operation is similar to that of the second embodiment.
(1) In the non-MIMO operation, the first transmission system 11 transmits one carrier's worth of the spectrum 61, and the second transmission system 12 transmits one carrier's worth of the spectrum 62.
(2) Since the signal to be transmitted is a multicarrier signal including the two subcarriers, the transmission system 13 may be halted in the non-MIMO operation. In addition, the transmission system 13 may be omitted when not used in the MIMO operation, either.
   Modification, etc.

The embodiments are described above, referring to, as an example, a wireless communication apparatus having three transmission systems and three reception systems. However, the present invention is of course not limited to this number, i.e., “3”. Moreover, the multicarrier signals illustrated in FIGS. 4 and 8 each have nine subcarriers, and the multicarrier signal illustrated in FIG. 6 has two subcarriers. However, the present invention is of course not limited to these numbers.

In the first embodiment described above, the output signal of the transmitting circuit 1 in the first transmission system 11 is distributed to each of the transmission power amplifiers 2 so that the power radiated from the respective transmitting antennas 3 in the transmission systems 11, 12, and 13 is equalized in the non-MIMO operation. From the viewpoint of improving the power added efficiency of each of the transmission power amplifiers 2, it is desirable, but not necessary, that the output signal be “evenly” distributed. For example, in the non-MIMO operation, the power of the transmission signal may be dispersed so that the operating output power of the transmission power amplifiers 2 in the transmission systems 11, 12, and 13 become 30 mW, 30 mW, and 40 mW (30 mW+30 mW +40 mW=100 mW), respectively, because even this division still can expect much better improvement in the power added efficiency than is achieved by the conventional example shown in FIG. 7.

In this case (where the power is not evenly distributed), considering even the signal's strength, it cannot be said that the respective transmitting antennas 3 in the transmission systems 11, 12, and 13 radiate mutually the “same signals”. However, it can be said that the signals radiated from the respective transmitting antennas 3 have mutually the same signal waveforms since these signals are obtained by amplifying the same signal from the transmitting circuit 1 in the transmission system 11. The “same signal waveforms” here is a concept not including the signal's strength, and thus becomes synonymous with “the same signals” if the signal's strength is equalized among these signals. Therefore, as one feature of the present invention, it can also be expressed that the signals of the same waveform are simultaneously transmitted from the respective transmitting antennas 3 to thereby divide the power of the transmission signal.

In the second embodiment described above, the nine subcarriers are evenly distributed to the three transmission systems 11, 12, and 13 (i.e., three for each) in the non-MIMO operation. From the viewpoint of improving the power added efficiency of each of the transmission power amplifiers 2, it is desirable, but not necessary, that these subcarriers be “evenly” distributed. For example, in the non-MIMO operation, the two, three, and four subcarriers may be distributed to the transmission systems 11, 12, and 13, respectively, because even this distribution still can expect much better improvement than is achieved by the conventional example shown in FIG. 7.

When a multicarrier signal includes, for example, ten subcarriers, the four, three, and three subcarriers may be distributed to the transmission systems 11, 12, and 13, respectively. This minimizes variation in the number of subcarriers distributed, thus resulting in the state closest to “even distribution”. Specifically, it is the most preferable that the ten subcarriers be dispersed for allocation so that the variation in the number of subcarriers allocated among the three transmission systems (4−3=1) is minimized.

The first and second embodiments described above refer to an example such that, in the non-MIMO operation, the power of the transmission signal is dispersed by using all the transmission power amplifiers 2 included in the transmission systems 11, 12, and 13. However, it is not necessary to use all the transmission power amplifiers 2.

For example, in the first embodiment, in the non-MIMO operation, the transmission power amplifiers 2 included in the transmission systems 11 and 12 may be operated at an operating output power of 50 mW while the transmission power amplifier 2 included in the transmission system 13 is halted.

For example, in the second embodiment, in transmitting the multicarrier signal including the nine subcarriers in the non-MIMO operation, the five and four subcarriers may be distributed to the transmission systems 11 and 12, respectively while the transmission system 13 is halted.

All the wireless communication apparatuses of the embodiments described above are based on the assumption that the MIMO transmission method is adopted. However, the MIMO transmission method is merely one example. Thus, the present invention is also applicable to wireless communication apparatuses which do not adopt the MIMO transmission method.

Specifically, in a wireless communication apparatus (hereinafter referred to as “wireless communication apparatus α) which includes three transmission systems 11, 12, and 13 and which is applicable to a transmission method for transmitting in parallel (simultaneously transmitting) three units of data having mutually different contents (hereinafter this transmission method is referred to as “transmission method α), the same operation as the non-MIMO operation in the embodiments described above may be performed to transmit a single unit of data without use of this transmission method α. The transmission method α corresponds to the leading concept of the MIMO transmission method. The number is of course not limited to the aforementioned “3”.

For example, in the wireless communication apparatus a described above, when the transmission method α is adopted, since the three units of data having mutually different contents are transmitted in parallel from the three transmission systems (11, 12, and 13), a power of approximately 33 mW is radiated from one transmission system in order to respect the upper limit of the transmission power, i.e., 100 mW. In transmitting a single unit of data without use of the transmission method α, as in the non-MIMO operation in the embodiments described above, the power of the transmission signal is dispersed by using a plurality of transmission power amplifiers 2. This can offer the same effects as is achieved by the wireless communication apparatus in the embodiments described above.

The wireless communication apparatus according to the present invention is preferably applicable to cellular phones, wireless LANs, and the like.

1. A wireless communication apparatus which is provided with M transmission systems, where M is an integer of two or more, each including therein a transmission amplifier for amplifying a signal received and a transmitting antenna for transmitting the amplified signal, and which is applicable to a transmission method for simultaneously transmitting a plurality of units of data having mutually different contents,
wherein, in transmitting a single unit of data without use of the transmission method, power of a transmission signal is dispersed for the transmission by use of a plurality of the transmission amplifiers included in the M transmission systems.

2. The wireless communication apparatus according to claim 1,
wherein, in transmitting the single unit of data without use of the transmission method, the power of the transmission signal is dispersed for the transmission by simultaneously transmitting signals of a same signal waveform from a plurality of the transmitting antennas corresponding to the plurality of the transmission amplifiers by use of the plurality of the transmission amplifiers.

3. The wireless communication apparatus according to claim 1,
wherein the plurality of the transmission amplifiers correspond to all the transmission amplifiers included in the M transmission systems.

4. The wireless communication apparatus according to claim 1,
wherein, in transmitting the single unit of data without use of the transmission method, the power of the transmission signal is dispersed for the transmission through even power allocation by use of the plurality of the transmission amplifiers.

5. The wireless communication apparatus according to claim 1,
wherein a modulated signal corresponding to the single unit of data is a multicarrier signal including N subcarriers, where N is an integer of two or more, and
wherein, in transmitting the single unit of data without use of the transmission method, the N subcarriers are dispersed for allocation to a plurality of the transmission systems in the M transmission systems, so that the plurality of the transmission systems independently amplify the respective mutually different subcarriers thereof and then independently transmit said subcarriers.

6. The wireless communication apparatus according to claim 5,
wherein the plurality of the transmission systems correspond to all the transmission systems in the M transmission systems.

7. The wireless communication apparatus according to claim 5,
wherein, in transmitting the single unit of data without use of the transmission method, the N subcarriers are dispersed for the allocation so as to minimize variation in a number of the subcarriers allocated among the plurality of the transmission systems.

8. The wireless communication apparatus according to claim 1,
wherein the transmission method is a MIMO transmission method.
